(19) United States
(12) Patent Application Publication
(10) Pub. No.: US 2021/0295487 A1
(43) Pub. Date: Sep. 23, 2021

(54) CRIMPING JUDGMENT METHOD

(71) Applicant: KABUSHIKI KAISHA TOSHIBA, Tokyo (JP)

(72) Inventors: Akira TANAKA, Yokohama (JP); Masaya HIRASHIMA, Yokohama (JP)

(73) Assignee: KABUSHIKI KAISHA TOSHIBA, Tokyo (JP)

(21) Appl. No.: 17/074,750

(22) Filed: Oct. 20, 2020

(30) Foreign Application Priority Data
Mar. 23, 2020 (JP) 2020-050835

(51) Int. Cl. G06T 7/00; H01R 43/048; G01R 31/67

(52) U.S. Cl. CPC G06T 7/001; H01R 43/048; G06T 2207/30164; G06T 2200/04; G06T 2207/30136; G01R 31/67

(57) ABSTRACT

According to one embodiment, a crimping judgment method is a method of judging a goodness of a crimped state of a wire harness including a crimping terminal crimped to an electrical wire. The crimping judgment method includes a first process, a second process, and a third process. The first process includes acquiring image data of a crimped portion of the wire harness. The second process includes determining first data, which is numerical data, of a void of the crimped portion from the image data. The third process includes judging the goodness of the crimped state of the crimped portion based on the first data.

### CROSS-REFERENCE TO RELATED APPLICATIONS

This application is based upon and claims the benefit of priority from Japanese Patent Application No. 2020-050835, filed on Mar. 23, 2020; the entire contents of which are incorporated herein by reference.

### FIELD

Embodiments described herein relate generally to a crimping judgment method.

### BACKGROUND

A wire harness in which a crimping terminal is crimped to an electrical wire is utilized in the wiring of an electronic device at connections of sections having high wattage such as a power supply system or the like. If the crimping terminal is insufficiently crimped to the electrical wire in such a wire harness, there is a risk that oxidization or detachment of the electrical wire may occur, and the resistance value may increase and cause heat generation, smoke emission, etc.

Therefore, when manufacturing a wire harness, a judgment method that can accurately judge the goodness of the crimped state is desirable. For example, in a known method, the goodness of the crimped state is judged based on a cross section observation of the crimped portion of the wire harness, the crimp height of the crimped portion, etc. However, there are cases where the goodness of the crimped state cannot be accurately judged in a crimping judgment method that is based on the cross section observation, the crimp height of the crimped portion, etc.

### BRIEF DESCRIPTION OF THE DRAWINGS

FIG. 1 is a plan view schematically illustrating a wire harness according to an embodiment;

FIGS. 2A to 2C are cross-sectional views schematically illustrating examples of the crimped portion of the wire harness;

FIG. 3 is a flowchart illustrating a crimping judgment method according to a first embodiment;

FIG. 4 is a descriptive view schematically illustrating a technique for determining a two-dimensional void fraction;

FIG. 5 is a flowchart illustrating a crimping judgment method according to a second embodiment;

FIG. 6 is a descriptive view schematically illustrating a technique for determining a three-dimensional void fraction;

FIG. 7 is a flowchart illustrating a crimping judgment method according to a third embodiment; and

FIG. 8 is a flowchart illustrating a crimping judgment method according to a fourth embodiment.

### DETAILED DESCRIPTION

A crimping judgment method according to an embodiment is a method of judging a goodness of a crimped state of a wire harness including a crimping terminal crimped to an electrical wire. The crimping judgment method includes a first process, a second process, and a third process. The first process includes acquiring image data of a crimped portion of the wire harness. The second process includes determining first data, which is numerical data, of a void of the crimped portion from the image data. The third process includes judging the goodness of the crimped state of the crimped portion based on the first data.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with the same reference numerals, and a detailed description is omitted as appropriate.

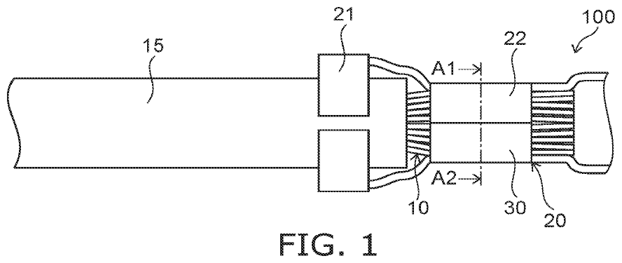

FIG. 1 is a plan view schematically illustrating a wire harness according to an embodiment.

As illustrated in FIG. 1, the wire harness 100 includes an electrical wire 10, and a crimping terminal 20 that is mounted to a tip of the electrical wire 10.

The wire harness 100 includes multiple electrical wires 10. A portion of the electrical wires 10 is covered with an insulating cover member 15. The electrical wires 10 include, for example, a metal such as aluminum, copper, copper alloy, etc. The crimping terminal 20 includes, for example, a metal such as aluminum, copper, copper alloy, etc., that may have plated surfaces.

The crimping terminal 20 includes a first mounting portion 21 that is mounted to the cover member 15, and a second mounting portion 22 that is mounted to the electrical wires 10. The first mounting portion 21 is mounted to cover the periphery of the cover member 15 covering the electrical wires 10. In other words, the first mounting portion 21 is mounted to the portion of the electrical wires 10 covered with the cover member 15. The first mounting portion 21 is fixed to the cover member 15 by mashing (caulking) the first mounting portion 21 to cover the periphery of the cover member 15.

The second mounting portion 22 is mounted to cover the periphery of the electrical wires 10. In other words, the second mounting portion 22 is mounted to a portion of the electrical wires 10 not covered with the cover member 15. The second mounting portion 22 is fixed to the electrical wires 10 by mashing (caulking) the second mounting portion 22 to cover the periphery of the electrical wires 10. Thereby, the second mounting portion 22 is electrically connected to the electrical wires 10. That is, the second mounting portion 22 is crimped to the electrical wires 10. Thus, the wire harness 100 includes a crimped portion 30 at which the crimping terminal 20 (the second mounting portion 22) is crimped to the electrical wires 10.

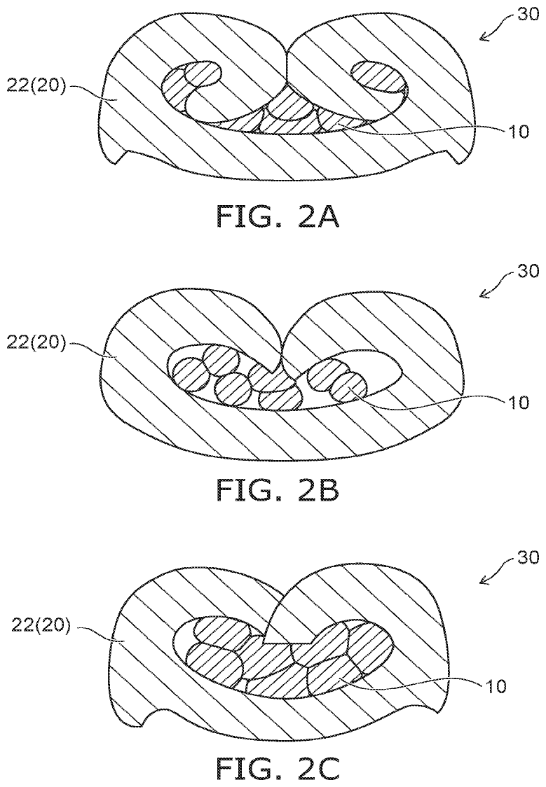

FIGS. 2A to 2C are cross-sectional views schematically illustrating examples of the crimped portion of the wire harness.

FIGS. 2A to 2C are cross-sectional views along line A1-A2 shown in FIG. 1.

In the crimped portion 30 as illustrated in FIGS. 2A to 2C, the electrical wires 10 are inside the crimping terminal 20 (the second mounting portion 22). That is, in the crimped portion 30, the electrical wires 10 are positioned in a space surrounded with the crimping terminal 20 (the second mounting portion 22). Therefore, it is difficult to accurately judge the goodness of the crimped state from only the appearance of the crimped portion 30.

As illustrated in FIG. 2A, a large void does not occur between the crimping terminal 20 and the electrical wires 10 when the crimped state is good. On the other hand, when the crimped state is defective as illustrated in FIG. 2B, a large void occurs between the crimping terminal 20 and the electrical wires 10. Thus, the goodness of the crimped state can be somewhat estimated by observing the cross section of the crimped portion 30.

However, for example, when there is a void between the crimping terminal 20 and the electrical wires 10 and the void is small as illustrated in FIG. 2C, etc., it is difficult to judge the goodness of the crimped state. That is, it is difficult to accurately judge the goodness of the crimped state only by qualitatively evaluating the state of the cross section by observing the cross section of the crimped portion 30.

### First Embodiment

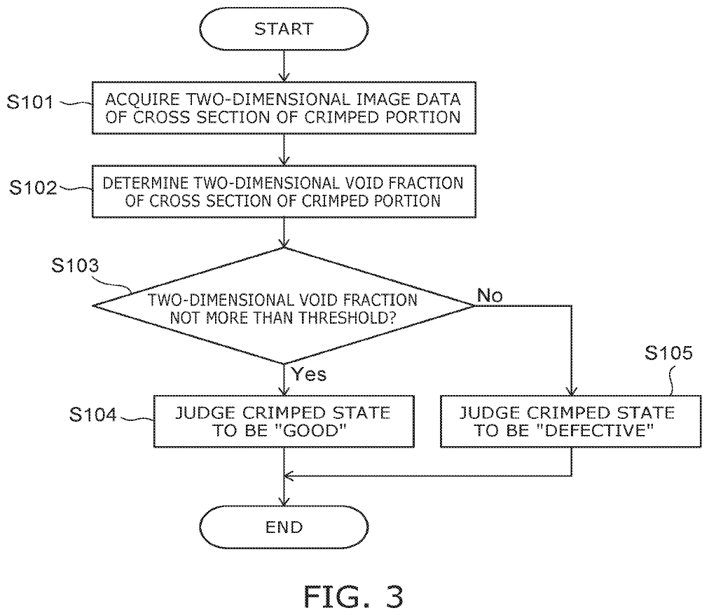

FIG. 3 is a flowchart illustrating a crimping judgment method according to a first embodiment.

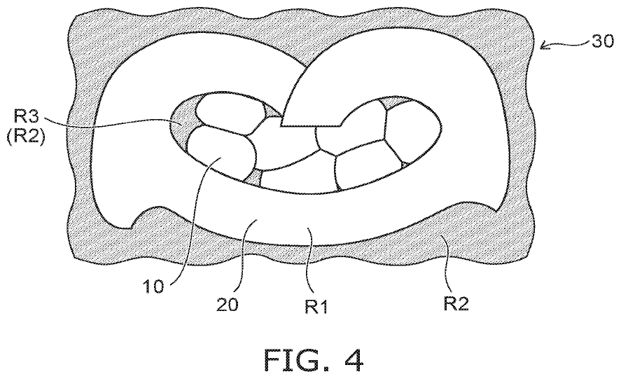

FIG. 4 is a descriptive view schematically illustrating a technique for determining a two-dimensional void fraction.

In the crimping judgment method according to the first embodiment as illustrated in FIG. 3, first, image data of the crimped portion 30 of the wire harness 100 is acquired (a first process; step S101). In the example, two-dimensional image data of the cross section of the crimped portion 30 is acquired as the image data.

For example, the two-dimensional image data of the cross section of the crimped portion 30 can be acquired by cutting the wire harness 100 at the crimped portion 30 and by imaging the cross section by using an optical microscope, a metallurgical microscope, an electron microscope, etc.

At this time, the image data may be acquired after injecting a metal having a larger atomic number than the metal (e.g., aluminum or copper) included in the crimping terminal 20 into the crimped portion 30. In such a case, for example, silver, gold, tin, lead, molybdenum, etc., are examples of the metal that is used. More specifically, for example, solder (eutectic or lead-free), a silver paste, a gold paste, tin plating, etc., can be used.

Then, from the image data acquired in the first process (step S101), numerical data (hereinbelow, called “first data”) of the void of the crimped portion 30 is determined (a second process; step S102). In the example, numerical data of the two-dimensional void of the cross section of the crimped portion 30 is determined as the first data from the two-dimensional image data acquired in step S101. Herein, “numerical data of the two-dimensional void” is the two-dimensional void fraction, the two-dimensional void shape, the two-dimensional void size, etc. In the example, the two-dimensional void fraction is determined as the first data in step S102.

The two-dimensional void fraction can be determined as follows. First, as illustrated in FIG. 4, the two-dimensional image data is binarized and divided into a first region R1 in which the electrical wires 10 and the crimping terminal 20 exist, and a second region R2 in which the electrical wires 10 and the crimping terminal 20 do not exist. The portion of the second region R2 that is inside the first region R1 can be considered to be a void region R3 that corresponds to the void between the crimping terminal 20 and the electrical wires 10 and the void between the electrical wires 10. A two-dimensional void fraction Pa is represented by the ratio of a surface area S3 of the void region R3 to a sum of a surface area S1 of the first region R1 and the surface area S3 of the void region R3 (Pa=S3/(S1+S3)).

Also, by binarizing the two-dimensional image data, the location of the void region R3 with respect to the first region R1 can be represented with a binary matrix. The two-dimensional void shape can be determined from the matrix. Also, the surface area S3 of the void region R3 can be determined by binarizing the two-dimensional image data. The two-dimensional void size can be determined from the surface area S3.

Then, based on the first data determined in the second process (step S102), the goodness of the crimped state of the crimped portion 30 is judged (a third process; step S103). In the example, the goodness of the crimped state of the crimped portion 30 is judged based on the two-dimensional void fraction determined in step S102. If the two-dimensional void fraction is not more than a threshold (step S103: Yes), the crimped state of the crimped portion 30 is judged to be “good” (step S104). On the other hand, if the two-dimensional void fraction is greater than the threshold (step S103: No), the crimped state of the crimped portion 30 is judged to be “defective” (step S105).

For example, the threshold of the two-dimensional void fraction can be determined from at least one of two-dimensional void fractions of good parts or two-dimensional void fractions of defective parts that are previously manufactured. Similarly, for example, the threshold of the two-dimensional void size can be determined from at least one of two-dimensional void sizes of good parts or two-dimensional void sizes of defective parts that are previously manufactured. When the two-dimensional void shape is used in the judgment, for example, the goodness of the crimped state can be judged by determining a matrix used as a reference of the judgment from at least one of two-dimensional void shapes of good parts or two-dimensional void shapes of defective parts that are previously manufactured, and by comparing (e.g., determining the degree of similarity) to the matrix used as the reference.

In a third process (step S103), the judgment may be performed based on one of the first data (e.g., one of the void fraction, the void shape, the void size, etc.), or the judgment may be performed based on a plurality of the first data (e.g., two or more of the void fraction, the void shape, the void size, etc.). When the judgment is performed based on a plurality of the first data in the third process (step S103), the plurality of the first data is determined from the image data in the second process (step S102).

Thus, the goodness of the crimped state can be quantitatively judged by acquiring the image data of the crimped portion 30, determining the numerical data (the first data) of the void of the crimped portion 30 from the acquired image data, and judging the goodness of the crimped state of the crimped portion 30 based on the first data. Accordingly, the goodness of the crimped state of the wire harness 100 can be more accurately judged without requiring a person having expert judgment skill.

By determining the void fraction from the image data and by judging based on the void fraction, the goodness of the crimped state can be more easily and accurately judged compared to the judgment using the void shape and/or the void size.

Also, the goodness of the crimped state can be more easily judged by acquiring two-dimensional image data of the cross section of the crimped portion, determining two-dimensional first data of the cross section from the two-dimensional image data, and performing the judgment based on the two-dimensional first data.

In the first process, the void can be more easily extracted by acquiring image data in which a contrast difference is provided by injecting a metal having a larger atomic number than the metal included in the crimping terminal 20 into the crimped portion 30. Accordingly, the state of the void of the crimped portion 30 can be more accurately ascertained, and the goodness of the crimped state can be more accurately judged.

### Second Embodiment

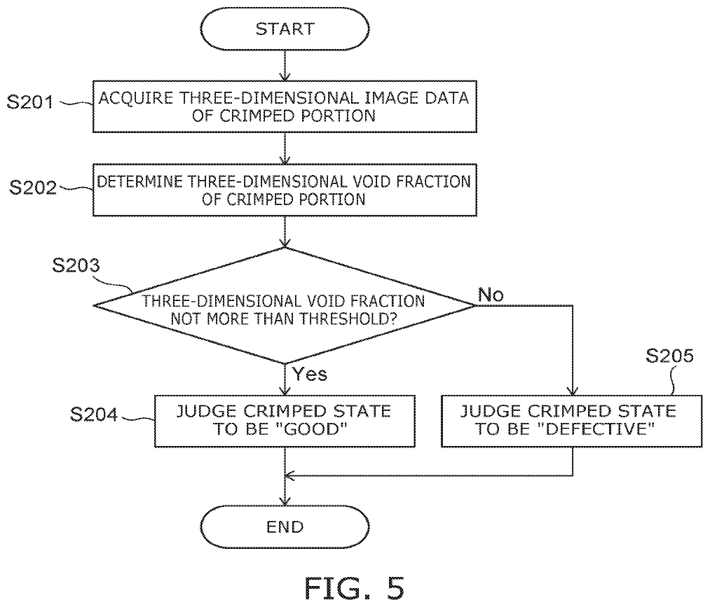

FIG. 5 is a flowchart illustrating a crimping judgment method according to a second embodiment.

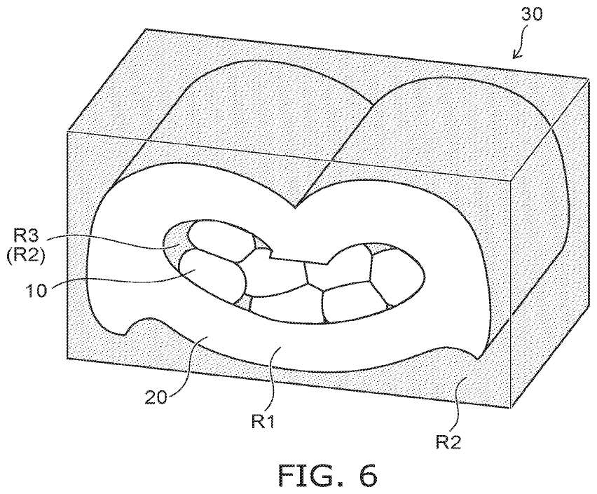

FIG. 6 is a descriptive view schematically illustrating a technique for determining a three-dimensional void fraction.

In the crimping judgment method according to the second embodiment as illustrated in FIG. 5, first, image data of the crimped portion 30 of the wire harness 100 is acquired (the first process; step S201). In the example, three-dimensional image data of the crimped portion 30 is acquired as the image data.

For example, the three-dimensional image data of the cross section of the crimped portion 30 can be acquired by imaging the crimped portion 30, for example, X-ray CT (Computed Tomography). At this time, similarly to the first embodiment, the image data can be acquired after injecting a metal having a larger atomic number than one of the metal included in the electrical wires 10 or the metal included in the crimping terminal 20 into the crimped portion 30.

Then, from the image data acquired in the first process (step S201), numerical data (the first data) of the void of the crimped portion 30 is determined (the second process; step S202). In the example, numerical data of the three-dimensional void of the crimped portion 30 is determined as the first data from the three-dimensional image data acquired in step S201. Herein, “numerical data of the three-dimensional void” is the three-dimensional void fraction, the three-dimensional void shape, the three-dimensional void size, etc. In the example, the three-dimensional void fraction is determined as the first data in step S202.

The three-dimensional void fraction can be determined as follows. First, as illustrated in FIG. 6, the three-dimensional image data is binarized and divided into the first region R1 in which the electrical wires 10 and the crimping terminal 20 exist, and the second region R2 in which the electrical wires 10 and the crimping terminal 20 do not exist. The portion of the second region R2 that is inside the first region R1 can be considered to be the void region R3 that corresponds to the void between the crimping terminal 20 and the electrical wires 10 and the void between the electrical wires 10. A three-dimensional void fraction Pb is represented by the ratio of a volume V3 of the void region R3 to the sum of a volume V1 of the first region R1 and the volume V3 of the void region R3 (Pb=V3/(V1+V3)).

Also, by binarizing the three-dimensional image data, the location of the void region R3 with respect to the first region R1 can be represented by a binary matrix. The three-dimensional void shape can be determined from the matrix. Also, the volume V3 of the void region R3 can be determined by binarizing the three-dimensional image data. The three-dimensional void size can be determined from the volume V3.

Then, based on the first data determined in the second process (step S202), the goodness of the crimped state of the crimped portion 30 is judged (the third process; step S203). In the example, the goodness of the crimped state of the crimped portion 30 is judged based on the three-dimensional void fraction determined in step S202. If the three-dimensional void fraction is not more than a threshold (step S203: Yes), the crimped state of the crimped portion 30 is judged to be “good” (step S204). On the other hand, if the three-dimensional void fraction is greater than the threshold (step S203: No), the crimped state of the crimped portion 30 is judged to be “defective” (step S205).

For example, the threshold of the three-dimensional void fraction can be determined from at least one of three-dimensional void fractions of good parts or three-dimensional void fractions of defective parts that are previously manufactured. Similarly, for example, the threshold of the three-dimensional void size can be determined from at least one of three-dimensional void sizes of good parts or three-dimensional void sizes of defective parts that are previously manufactured. When the three-dimensional void shape is used in the judgment, for example, the goodness of the crimped state can be judged by determining a matrix used as the reference of the judgment from at least one of three-dimensional void shapes of good parts or three-dimensional void shapes of defective parts that are previously manufactured and by comparing (e.g., determining the degree of similarity) to the matrix used as the reference.

In the third process (step S203), the judgment may be performed based on one of the first data (e.g., one of the void fraction, the void shape, the void size, etc.), or the judgment may be performed based on a plurality of the first data (e.g., two or more of the void fraction, the void shape, the void size, etc.). When the judgment is performed based on a plurality of the first data in the third process (step S203), the plurality of the first data is determined from the image data in the second process (step S202).

There are cases where the state of the void of the crimped portion 30 is different according to the cut position (the position of the cross section). In such a case, even for the same crimped portion 30 of the wire harness 100, there is a risk that the crimped state may be judged to be “good” or judged to be “defective” according to the position of the cross section. That is, when the judgment is performed based on the two-dimensional first data, there are cases where the state of the void is different according to the position of the cross section, and it is difficult to accurately judge the goodness of the crimped state.

Conversely, by acquiring three-dimensional image data of the crimped portion, by determining three-dimensional first data of the crimped portion from the three-dimensional image data, and by judging based on the first data, the state of the void of the crimped portion 30 can be more accurately ascertained even when the state of the void is different according to the position of the cross section. Accordingly, compared to when the judgment is performed based on two-dimensional first data, the goodness of the crimped state can be more accurately judged. According to this method, a non-destructive goodness judgment of the crimped state can be performed.

Three-dimensional image data of the crimped portion 30 may be acquired in the first process (step S201); two-dimensional first data (the two-dimensional void fraction, the two-dimensional void shape, the two-dimensional void size, etc.) may be determined for the cross section at any position in the second process (step S202); and the goodness of the crimped state of the crimped portion 30 may be judged based on the two-dimensional first data in the third process (step S203). In such a case, for example, the position of the cross section can be set to the position at which the void fraction is smallest.

### Third Embodiment

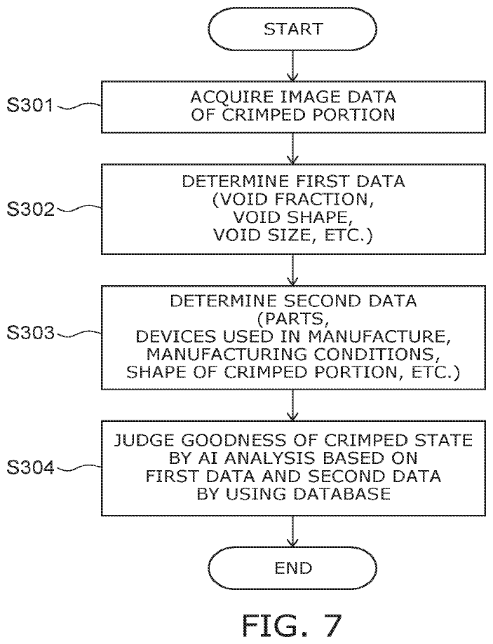

FIG. 7 is a flowchart illustrating a crimping judgment method according to a third embodiment.

In the crimping judgment method according to the third embodiment as illustrated in FIG. 7, first, image data of the crimped portion 30 of the wire harness 100 is acquired (the first process; step S301). At this time, as the image data, two-dimensional image data of the cross section of the crimped portion 30 may be acquired as in the first embodiment, or three-dimensional image data of the crimped portion 30 may be acquired as in the second embodiment.

Then, from the image data acquired in the first process (step S301), numerical data (the first data) of the void of the crimped portion 30 is determined (the second process; step S302). At this time, as the first data, two-dimensional first data may be determined as in the first embodiment, or three-dimensional first data may be determined as in the second embodiment.

Then, data (hereinbelow, called “second data”) other than the first data determined in the second process (step S302) is determined (step S303). The second data is, for example, at least one of data of the parts used in the wire harness (the material, the size, etc., of the electrical wire and/or the crimping terminal), data of the devices used in the manufacture (an applicator, a crimping tool, etc.), data of the manufacturing conditions (the pressure when crimping, the crimping time, etc.), or data of the shape of the crimped portion of the wire harness (the crimp height, the crimp width, etc.). The second data may be determined from the image data acquired in the first process (step S301).

Step S303 may be performed before step S301 or may be simultaneously performed with step S301. Also, step S303 may be performed between step S301 and step S302 or may be simultaneously performed with step S302.

Then, based on the first data determined in the second process (step S302) and the second data determined in step S303, the goodness of the crimped state of the crimped portion 30 is judged (the third process; step S304). At this time, the goodness of the crimped state is judged by AI analysis using a database storing at least one of data of good parts or data of defective parts. For example, the database stores at least one of the first data of good parts or the first data of defective parts and at least one of the second data of good parts or the second data of defective parts.

In this specification, “AI analysis” is analysis that uses AI (Artificial Intelligence). In the judgment by AI analysis, the goodness of the crimped state is judged by a prescribed algorithm using the data stored in the database. Herein, a “prescribed algorithm” judges the goodness of the crimped state by combining multiple data. In the judgment by AI analysis, for example, the goodness of the crimped state is judged based on a reference determined by machine learning using the data stored in the database. In the judgment by AI analysis, for example, the goodness of the crimped state is judged based on a reference determined by “supervised learning” in which data of good parts and data of defective parts are teacher data.

In the example, at least one of the multiple data used in the judgment by AI analysis is the first data determined in step S302. Also, at least one of the multiple data used in the judgment by AI analysis is the second data determined in step S303. That is, in the example, the judgment is performed by AI analysis based on at least one of the first data and at least one of the second data. A plurality of the first data and a plurality of the second data may be included in the multiple data used in the judgment by AI analysis.

In the judgment by AI analysis, for example, AI may select the data (parameters) of the first data to be used in the judgment based on the data stored in the database. Also, in the judgment by AI analysis, for example, AI may select the data (parameters) of the second data to be used in the judgment based on the data stored in the database. In the judgment by AI analysis, for example, AI may determine the weight of each of the data used in the judgment based on the data stored in the database.

### Fourth Embodiment

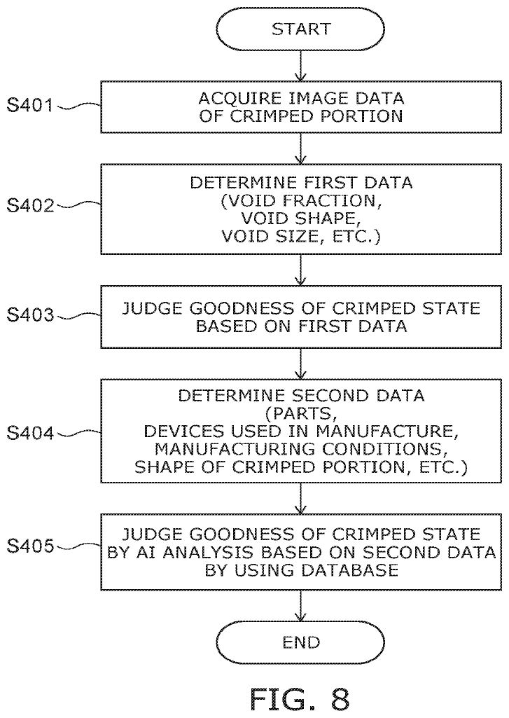

FIG. 8 is a flowchart illustrating a crimping judgment method according to a fourth embodiment.

In the crimping judgment method according to the fourth embodiment as illustrated in FIG. 8, first, image data of the crimped portion 30 of the wire harness 100 is acquired (the first process; step S401). Then, from the image data acquired in the first process (step S401), the first data is determined (the second process; step S402). Step S401 and step S402 can be performed respectively similarly to step S301 and step S302 of the third embodiment.

Then, based on the first data determined in the second process (step S402), the goodness of the crimped state of the crimped portion 30 is judged (the third process; step S403). For example, step S403 can be performed similarly to steps S103 to S105 of the first embodiment or steps S203 to S205 of the second embodiment.

Then, when the crimped state is judged to be “good” in step S403, the second data is determined (step S404). Step S404 can be performed similarly to step S303 of the third embodiment.

Step S404 may be performed before step S401 or may be simultaneously performed with step S401. Also, step S404 may be performed between step S401 and step S402 or may be simultaneously performed with step S402. Also, step S404 may be performed between step S402 and step S403 or may be simultaneously performed with step S403.

Then, based on the second data determined in step S404, the goodness of the crimped state of the crimped portion 30 is judged (step S405). At this time, the goodness of the crimped state is judged by AI analysis using the database storing at least one of data of good parts or data of defective parts. Step S405 can be performed similarly to step S304 of the third embodiment. However, in the example, all of the multiple data used in the judgment by AI analysis is the second data determined in step S404. That is, in step S405, the judgment is performed by AI analysis based on two or more data of the second data. In the example, steps S403 to S405 can be considered to be the third process.

Thus, in the judgment by AI analysis, the judgment based on the first data and the judgment based on the second data may be performed simultaneously or separately. In other words, in the third process, the judgment may be performed once by AI analysis based on the first and second data as shown in the third embodiment, or the judgment may be divided into two, i.e., the judgment based on the first data and the judgment by AI analysis based on the second data as shown in the fourth embodiment.

In the fourth embodiment, the judgment based on the second data is performed (step S405) when the judgment of the crimped state is “good” in the judgment based on the first data (step S403). That is, the part is judged to be a good part when the crimped state is judged to be “good” for both the judgment based on the first data (step S403) and the judgment based on the second data (step S405). In the fourth embodiment, for example, the judgment based on the second data (step S405) may be performed when the crimped state is judged to be “defective” in the judgment based on the first data (step S403). That is, the part may be judged to be a good part when the crimped state is judged to be “good” for at least one of the judgment based on the first data (step S403) or the judgment based on the second data (step S405).

According to the embodiments as described above, a crimping judgment method is provided in which the goodness of the crimped state of a wire harness including a crimping terminal crimped to an electrical wire can be more accurately judged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. The above embodiments can be practiced in combination with each other.

What is claimed is:

1. A crimping judgment method of judging a goodness of a crimped state of a wire harness including a crimping terminal crimped to an electrical wire, the method comprising:
a first process of acquiring image data of a crimped portion of the wire harness;
a second process of determining first data of a void of the crimped portion from the image data, the first data being numerical data; and
a third process of judging a goodness of a crimped state of the crimped portion based on the first data.

2. The method according to claim 1, wherein
the third process includes using a database storing at least one of data of good parts or data of defective parts to judge the goodness of the crimped state of the crimped portion by AI analysis based on the first data and second data, and
the second data is data other than the first data.

3. The method according to claim 1, wherein
the second process includes determining a void fraction of the crimped portion as the first data, and
the third process includes judging the crimped state to be good if the void fraction is not more than a threshold, and judging the crimped state to be defective if the void fraction is greater than the threshold.

4. The method according to claim 1, wherein
the first process includes acquiring two-dimensional image data of a cross section of the crimped portion as the image data, and
the second process includes determining, as the first data, numerical data of a two-dimensional void of the cross section from the two-dimensional image data.

5. The method according to claim 1, wherein
the first process includes acquiring three-dimensional image data of the crimped portion as the image data, and
the second process includes determining, as the first data, numerical data of a three-dimensional void of the crimped portion from the three-dimensional image data.

6. The method according to claim 1, wherein
the first process includes acquiring the image data of the crimped portion after injecting a metal into the crimped portion, the metal having a larger atomic number than a metal included in the crimping terminal.
